(19) United States
(12) Patent Application Publication
(10) Pub. No.: US 2020/0279915 A1
(43) Pub. Date: Sep. 3, 2020

(54) HIGH-VOLTAGE SEMICONDUCTOR DEVICE WITH INCREASED BREAKDOWN VOLTAGE AND MANUFACTURING METHOD THEREOF

(71) Applicant: Yangtze Memory Technologies Co., Ltd., Wuhan City (CN)

(72) Inventor: Chao Sun, Wuhan City (CN)

(21) Appl. No.: 16/540,069

(22) Filed: Aug. 14, 2019

Related U.S. Application Data
(63) Continuation of application No. PCT/CN2019/076413, filed on Feb. 28, 2019.

(51) Int. Cl. H01L 29/06; H01L 29/78; H01L 29/66

(52) U.S. Cl. CPC H01L 29/0653; H01L 29/7833; H01L 29/66568; H01L 29/7835; H01L 29/0692

(57) ABSTRACT

High voltage semiconductor device and manufacturing method thereof are disclosed. The high voltage semiconductor device includes a semiconductor substrate, a gate structure on the semiconductor substrate, at least one first isolation structure, and at least on first drift region. The first isolation structure and the first drift region are disposed in the semiconductor substrate at a side of the gate structure. The first isolation structure vertically penetrates through the first drift region.

### CROSS REFERENCE TO RELATED APPLICATIONS

This application is a continuation of International Application No. PCT/CN 2019/076413 filed Feb. 28, 2019, the entire contents of which are incorporated herein by reference.

### BACKGROUND OF THE INVENTION

### 1. Field of the Invention

The present invention relates to a semiconductor device and a manufacturing method thereof, and more particularly, to a high voltage semiconductor device with an increased breakdown voltage and a manufacturing method thereof.

### 2. Description of the Prior Art

In general metal-oxide-semiconductor (MOS) transistors, since drain region overlaps gate electrode, electrical breakdown easily occurs at the overlapping region of the drain region and the gate electrode due to the effect of the gate induced drain leakage (GIDL). Especially, in an application of peripheral circuit of flash, for example in 3D NAND flash, higher and higher erasing voltage for trinary-level cell (TLC) or quad-level cell (QLC) is required, so the MOS transistors for controlling the TLC or QLC need higher breakdown voltage.

In order to increasing breakdown voltage of the MOS transistor, a planar high-voltage MOS transistor is developed to have an extended drain so as to exhibit a high breakdown voltage, such as drain extended MOS (DEMOS). Another method is developed to further have an isolation structure in the drain so as to increase the breakdown voltage at drain, such as lateral diffusion MOS (LDMOS). However, these methods enlarge the top-view area of the MOS transistor, which limit the reduction of the size of the device with the MOS transistors. Another method is to fabricate a gate oxide layer with a shape of staircase so as to increase the thickness of the gate oxide layer between the gate electrode and the drain region, but this method requires extra mask and extra process, thereby increasing manufacturing cost. As a result, to increasing the breakdown voltage of the MOS transistor with no enlarged area and less increased cost is always in need.

### SUMMARY OF THE INVENTION

Embodiments of a high voltage semiconductor device and a manufacturing method thereof are described in the present invention.

In some embodiments, a high voltage semiconductor device is disclosed. The high voltage semiconductor device includes a semiconductor substrate, a gate structure, at least one first isolation structure, and at least one first drift region. The semiconductor substrate has an active area, and the semiconductor substrate has a first conductivity type. The gate structure is disposed on the active area of the semiconductor substrate. The at least one first isolation structure is disposed in the active area of the semiconductor substrate at a side of the gate structure. The at least one first drift region is disposed in the active area of the semiconductor substrate at the side of the gate structure, and the at least one first drift region has a second conductivity type complementary to the first conductivity type, in which the at least one first isolation structure vertically penetrates through the at least one first drift region.

In some embodiments, the high voltage semiconductor device further includes at least one first doped region disposed in the at least one first drift region, and the at least one first isolation structure is disposed between the at least one first doped region and the gate structure, in which the at least one first doped region has the second conductivity type.

In some embodiments, a doping concentration of the at least one first drift region is less than a doping concentration of the at least one first doped region

In some embodiments, the at least one first doped region is disposed between two opposite edges of the at least one first isolation structure in an extending direction of the gate structure.

In some embodiments, the at least one first drift region surrounds the at least one first isolation structure in a top view.

In some embodiments, the high voltage semiconductor device further includes a second isolation structure disposed in the semiconductor substrate, wherein the second isolation structure has an opening for defining the active area.

In some embodiments, the at least one first isolation structure is separated from the second isolation structure.

In some embodiments, a bottom of the second isolation structure is deeper than a bottom of the at least one first drift region.

In some embodiments, the high voltage semiconductor device further includes at least one second doped region disposed in the active area of the semiconductor substrate at another side of the gate structure, and the second doped region has the second conductivity type.

In some embodiments, the high voltage semiconductor device further includes at least one second drift region, disposed in the active area of the semiconductor substrate at the another side of the gate structure, and the at least one second doped region being disposed in the at least one second drift region, wherein the at least one second drift region has the second conductivity type, and a doping concentration of the at least one second drift region is less than a doping concentration of the at least one second doped region.

In some embodiments, the high voltage semiconductor device further includes a third isolation structure disposed in the active area of the semiconductor substrate between the at least one second doped region and the gate structure, and the third isolation structure vertically penetrates through the at least one second drift region.

In some embodiments, the at least one second doped region is disposed between two opposite edges of the third isolation structure in an extending direction of the gate structure.

In some embodiments, the at least one first isolation structure includes a plurality of first isolation structures arranged along a direction perpendicular to an extending direction of the gate structure.

In some embodiments, the at least one first isolation structure includes a plurality of first isolation structures spaced apart from each other and arranged along an extending direction of the gate structure, the high voltage semiconductor device includes a plurality of the first doped regions, and the first doped regions fully overlap the first isolation structures in a direction perpendicular to the extending direction of the gate structure.

In some embodiments, a method for manufacturing a high voltage semiconductor device is disclosed. The method includes providing a semiconductor substrate having a first conductivity type, wherein the semiconductor substrate has an active area; forming at least one first isolation structure in the active area of the semiconductor substrate; forming a gate structure on the active area of the semiconductor substrate and at a side of the at least one first isolation structure; and forming at least one first drift region in the active area of the semiconductor substrate at a side of the gate structure, and the first drift region having a second conductivity type complementary to the first conductivity type, wherein a bottom of the at least one first isolation structure is deeper than a bottom of the at least one first drift region.

In some embodiments, the method further includes forming at least one first doped region in the at least on first drift region, wherein the at least one first doped region has the second conductivity type and the at least one first isolation structure is disposed between the gate structure and the at least one first doped region

In some embodiments, a doping concentration of the at least one first drift region is less than a doping concentration of the at least one first doped region.

In some embodiments, forming the at least one first isolation structure comprises forming a second isolation structure in the semiconductor substrate, wherein the second isolation structure has an opening defining the active area.

In some embodiments, the at least one first isolation structure is spaced apart from the second isolation structure.

me embodiments, forming the at least one first doped region includes forming at least one second doped region in the active area of the semiconductor substrate at another side of the gate structure, and the at least one second doped region has the second conductivity type.

In some embodiments, forming the first drift region includes forming at least one second drift region in the semiconductor substrate, the at least one second drift region has the second conductivity type, the at least one second doped region is disposed in the at least one second drift region, and a doping concentration of the at least one second drift region is less than a doping concentration of the at least one second doped region.

In some embodiments, forming the at least one first isolation structure includes forming a third isolation structure in the semiconductor substrate and between the at least one second doped region and the gate structure, and the third isolation structure vertically penetrates through the at least one second drift region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings, which are incorporated herein and form a part of the specification, illustrate embodiments of the present invention and, together with the description, further serve to explain the principles of the present invention and to enable a person skilled in the pertinent art to make and use the present invention.

FIG. 1A is a schematic diagram illustrating a top view of an exemplary HV semiconductor device according to a first embodiment of the present invention

FIG. 1B schematically illustrates a sectional view of the exemplary HV semiconductor device taken along a sectional line A-A′ of FIG. 1A.

FIG. 2 schematically illustrates breakdown voltages of the HV semiconductor device according to the first embodiment and a HV semiconductor device without the first isolation structure.

FIG. 3 schematically illustrates a flowchart of an exemplary method for manufacturing the HV semiconductor device according to the first embodiment.

FIG. 4A-FIG. 5A schematically illustrate top views of exemplary structures at different steps of the exemplary method.

FIG. 4B-FIG. 5B schematically illustrate sectional views of exemplary structures at different steps of the exemplary method.

FIG. 6 is a schematic diagram illustrating a top view of an exemplary HV semiconductor device according to a second embodiment of the present invention.

FIG. 7A is a schematic diagram illustrating a top view of an exemplary HV semiconductor device according to a third embodiment of the present invention

FIG. 7B schematically illustrates a sectional view of the exemplary HV semiconductor device taken along a sectional line B-B′ of FIG. 7A.

FIG. 8 is a schematic diagram illustrating a top view of an exemplary HV semiconductor device according to a fourth embodiment of the present invention.

Embodiments of the present invention will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present invention. It will be apparent to a person skilled in the pertinent art that the present invention can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present invention should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc.

As used herein, the term “substantially” refers to a desired, or target value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject photomask structure. Based on the particular technology node, the term “about” can indicate a value of a given quantity that varies within, for example, 10-30% of the value (e.g., ±10%, ±20%, or ±30% of the value).

As used throughout this application, the word “may” is used in a permissive sense (e.g., meaning having the potential to), rather than the mandatory sense (e.g., meaning must). The words “include”, “including”, and “includes” indicate open-ended relationships and therefore mean including, but not limited to. Similarly, the words “have”, “having”, and “has” also indicated open-ended relationships, and thus mean having, but not limited to. The terms “first”, “second”, “third,” and so forth as used herein are meant as labels to distinguish among different elements and may not necessarily have an ordinal meaning according to their numerical designation.

In the present invention, different technical features in different embodiments described in the following description can be combined, replaced, or mixed with one another to constitute another embodiment.

In the present invention, following exemplary high voltage (HV) semiconductor devices of embodiments may be implemented in any kind of semiconductor device, such as a peripheral circuit of flash memory, power device or other suitable devices.

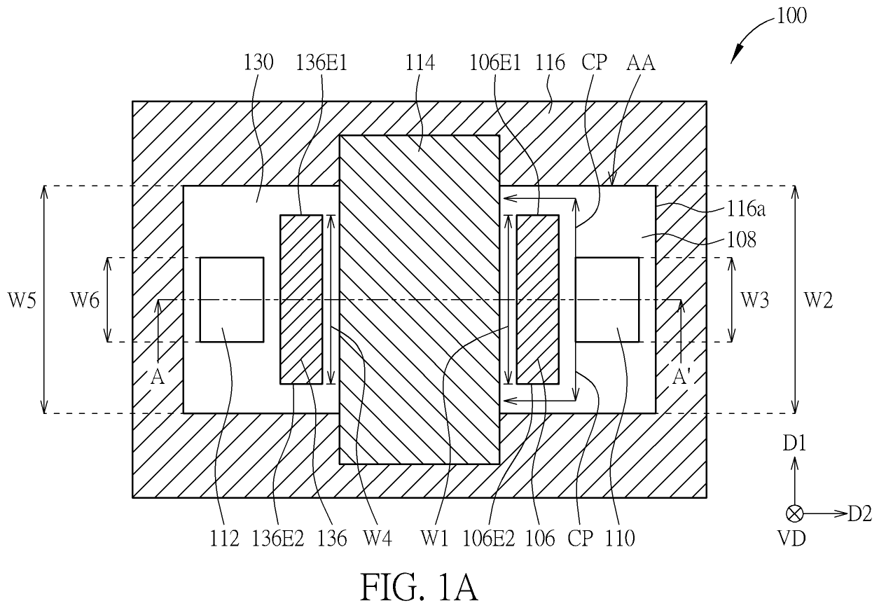

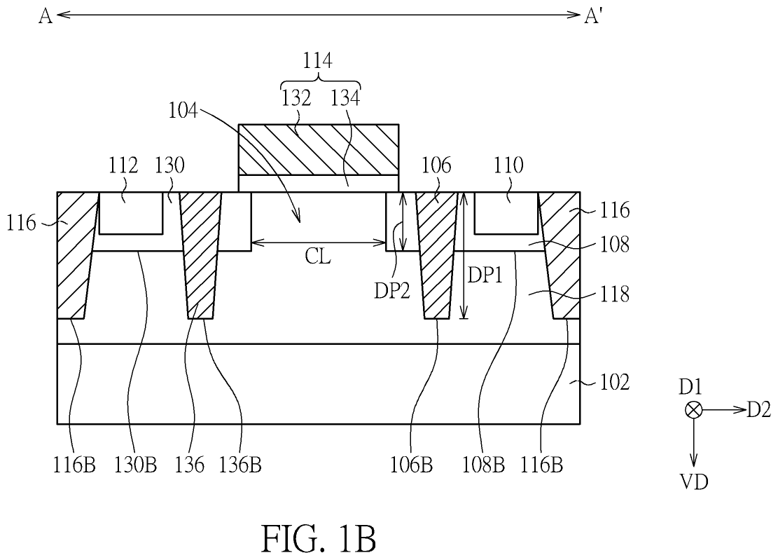

FIG. 1A is a schematic diagram illustrating a top view of an exemplary HV semiconductor device according to a first embodiment of the present invention, and FIG. 1B schematically illustrates a sectional view of the exemplary HV semiconductor device taken along a sectional line A-A′ of FIG. 1A. As shown in FIG. 1A and FIG. 1B, the HV semiconductor device 100 provided by this embodiment includes a semiconductor substrate 102, at least one first isolation structure 106, at least one first drift region 108, at least one first doped region 110, at least one second doped region 112, and a gate structure 114. The semiconductor substrate 102 has an active area AA for forming the HV semiconductor device 100. In some embodiments, the semiconductor substrate 102 may optionally include a well region 118 having a first conductivity type formed therein, and the well region 118 may serve as a base of the HV semiconductor device 100. In this situation, the semiconductor substrate 102 may have the first conductivity type or a second conductivity type complementing the first conductivity type, but the present invention is not limited thereto. The threshold voltage of the HV semiconductor device 100 can be adjusted for example based on the doping concentration of the well region 118. When the semiconductor substrate 102 has the same conductivity type as the well region 118, a doping concentration of the well region 118 may be greater than that of the semiconductor substrate 102, but not limited thereto. In some embodiments, the well region 118 may cover the active area AA in a top view. In some embodiments, the semiconductor substrate 102 may not include the well region formed therein, and the semiconductor substrate has the first conductivity type serves as the base of the HV semiconductor device 100. In some embodiments, the semiconductor substrate 102 includes any suitable material for forming the HV semiconductor device 100. For example, the semiconductor substrate 102 may include silicon, silicon germanium, silicon carbide, silicon on insulator (SOI), germanium on insulator (GOI), glass, gallium nitride, gallium arsenide, and/or other suitable III-V compound, but not limited thereto. In the present invention, the top view may be referred to as a vertical direction VD perpendicular to a top surface of the semiconductor substrate 102.

In some embodiments, the HV semiconductor device 100 may optionally further include a second isolation structure 116 that has an opening 116a for defining the active area AA. For example, the second isolation structure 116 surrounds the elements of the HV semiconductor device 100, such that the second isolation structure 116 may insulate the HV semiconductor device 100 from other devices formed in the same semiconductor substrate 102. In some embodiments, the second isolation structure 116 may be a shallow trench isolation (STI) or other suitable kinds of isolation structures.

The gate structure 114 is disposed on the active area AA of the semiconductor substrate 102. In this embodiment, the gate structure 114 may be a strip structure extending along a first direction D1 and across the active area AA. In some embodiments, the gate structure 114 may not be across the active area AA. In some embodiments, the gate structure 114 may include a gate electrode 132 serving as a gate of the HV semiconductor device 100 and a gate dielectric layer 134 disposed between the gate electrode 132 and the semiconductor substrate 102. In some embodiments, the gate structure 114 may further include spacer disposed at sidewalls of the gate electrode 132 and the gate dielectric layer 134.

The first isolation structure 106 is disposed in the active area AA of the semiconductor substrate 102 at a side of the gate structure 114. A width W1 of the first isolation structure 106 in an extending direction of the gate structure 114 (e.g. the first direction D1) is less than a width of the active area AA in the first direction D1. In some embodiments, the first isolation structure 106 is separated from the second isolation structure 116. In some embodiments, the first isolation structure 106 may be a STI or other suitable kinds of isolation structures. A width of the first isolation structure 106 in the second direction D2 may be adjusted according to the requirements of device characteristics.

The first drift region 108 is disposed in the active area AA of the semiconductor substrate 102 and on at least three sides of the first isolation structure 106 in the top view, and the first isolation structure 106 vertically penetrates through the first drift region 108. In other words, a bottom 106B of the first isolation structure 106 is deeper than a bottom 108B of the first drift region 108. It is noted that the first isolation structure 106 may penetrates through the first drift region 108 along the vertical direction VD. In some embodiments, the first drift region 108 may laterally surround the first isolation structure 106 in the top view. Accordingly, a shape of the first drift region 108 in the top view may be like “O” shape or ring shape. In some embodiments, an edge 106E1 or an edge 106E2 of the first isolation structure 106 may be connected to the second isolation structure 116, so the first drift region 108 may be disposed at the other three sides of the first isolation structure 106. The first drift region 108 may have a second conductivity type complementary to the first conductivity type. In some embodiments, the first drift region 108 may partially overlap the gate structure 114 in the top view. In some embodiments, the width W2 of the first drift region 108 in the first direction D1 may be defined by the second isolation structure 116 and accordingly may be substantially equal to the width of the active area AA in the first direction D1.

The first doped region 110 is disposed in the first drift region 108 and encompassed by the first drift region 108, and the first isolation structure 106 is disposed between the first doped region 110 and the gate structure 114. The first doped region 110 has the second conductivity type, and a doping concentration of the first drift region 108 is less than a doping concentration of the first doped region 110. The first doped region 110 may serve as a drain/source of the HV semiconductor device 100. In one embodiment, the first doped region 110 may be used as a drain/source terminal of the HV semiconductor device 100 for being connected to other outer devices or a power source; that is to say the first drift region 108 is electrically connected to the other outer devices only through the first doped region 110. It is noted that since the first isolation structure 106 is disposed between the first doped region 110 and the gate structure 114 and the first isolation structure 106 vertically penetrates the first drift region 108, the current path CP (as indicated by arrows shown in FIG. 1A) from the first doped region 110 to the semiconductor substrate 102 or well region 118 under the gate structure 114 should be around the first isolation structure 106 and will not be directly under the first isolation structure 106. Accordingly, the disposition of the first isolation structure 106 can reduce the effect of the electric field from the first doped region 110 on the gate structure 114, thereby enhancing the breakdown voltage at the drain/source of the HV semiconductor device 100. Through widening the width W1 of the first isolation structure 106 in the first direction D1, the current path CP can be lengthened. In this embodiment, the width W1 of the first isolation structure 106 in the first direction D1 may be greater than or equal to a width W3 of the first doped region 110 in the first direction D1. For example, the width W1 of the first isolation structure 106 in the first direction D1 may be between the width W3 of the first doped region 110 in the first direction D1 and the width W2 of the first drift region 108 in the first direction D1. In other words, the first doped region 110 is disposed between two opposite edges 106E1, 106E2 (that are the edges close to the second isolation structure 116) of the first isolation structure 106 in the first direction D1, and the first doped region 110 fully overlap the first isolation structure 106 in a direction perpendicular to the extending direction of the gate structure 114 (e.g. a second direction D2), so the current path CP from the first doped region 110 to the semiconductor substrate 102 or well region 118 under the gate structure 114 can be increased, thereby increasing the breakdown voltage at the drain/source of the HV semiconductor device 100 more significant. Also, the breakdown voltage may be adjusted for example based on the width W1 of the first isolation structure 106.

The second doped region 112 is disposed in the active area AA of the semiconductor substrate 102 at another side of the gate structure 114 opposite to the first drift region 108. The second doped region 112 has the second conductivity type and may serve as a source/drain of the HV semiconductor device 100, which means the second doped region 112 may be used as a source/drain terminal of the HV semiconductor device 110 for being connected to other outer devices or a power source.

In some embodiments, the HV semiconductor device 100 may optionally further include at least one second drift region 130 disposed in the active area AA of the semiconductor substrate 102 at the side of the gate structure 114 facing the second doped region 112, and the second doped region 112 is disposed in the second drift region 130 and encompassed by the second drift region 130. In such situation, the second drift region 130 has the second conductivity type, a doping concentration of the second drift region 130 is less than a doping concentration of the second doped region 112, and the second drift region 130 is electrically connected to the other outer devices only through the second doped region 112. In some embodiments, the second drift region 130 may partially overlap the gate structure 114 in the top view. In this situation, the semiconductor substrate 102 or the well region 118 between the first drift region 108 and the second drift region 130 and under the gate structure 114 may form a channel region 104 of the HV semiconductor device 100. In some embodiments, a width W5 of the second drift region 130 may be substantially equal to the width of the active area AA in the first direction D1.

In some embodiments, the HV semiconductor device 100 may optionally further include at least one third isolation structure 136 disposed in the active area AA of the semiconductor substrate 102 at the side of the gate structure 114 facing the second doped region 112. The third isolation structure 136 is disposed between the second doped region 112 and the gate structure 114. The second drift region 130 may be disposed at least three sides of the third isolation structure 136 in the top view. In some embodiments, the second drift region 130 may laterally surround the third isolation structure 136 in the top view. Accordingly, a shape of the second drift region 130 in the top view may also be like “O” shape or ring shape. In some embodiments, an edge of the third isolation structure 136 may be connected to the second isolation structure 116, so the second drift region 130 may be disposed at three sides of the third isolation structure 136. In some embodiments, the third isolation structure 136 may vertically penetrate through the second drift region 130. In other words, a bottom 136B of the third isolation structure 136 is deeper than a bottom 130B of the second drift region 130. In some embodiments, a width W4 of the third isolation structure 136 in the first direction D1 is less than the width W5 of the second drift region 130 in the first direction D1. A width of the third isolation structure 136 in the second direction D2 may be adjusted according to the requirements of device characteristics. In some embodiments, the third isolation structure 136 is separated from the second isolation structure 116. In some embodiments, the third isolation structure 136 may be a STI or other suitable isolation structures. In some embodiments, the first doped region 110, the first drift region 108 and the first isolation structure 106 may be respectively symmetrical to the second doped region 112, the second drift region 130 and the third isolation structure 136 with respect to the gate structure 114.

Since the third isolation structure 136 is similar to or has the same structure as the first isolation structure 106, the third isolation structure 136 may have the same function as the first isolation structure 106. Hence, the disposition of the third isolation structure 136 can reduce the effect of the electric field from the second doped region 112 on the gate structure 114, thereby enhancing the breakdown voltage at the source/drain of the HV semiconductor device 100. In this embodiment, the width W4 of the third isolation structure 136 in the first direction D1 is between the width W6 of the second doped region 112 in the first direction D1 and the width W5 of the second drift region 130 in the first direction D1. In other words, the second doped region 112 is disposed between two opposite edges 136E1, 136E2 of the third isolation structure 136 in the first direction D1, and the second doped region 112 fully overlap the third isolation structure 136 in a direction perpendicular to the extending direction of the gate structure 114 (e.g. the second direction D2), so the current path from the second doped region 112 to the semiconductor substrate 102 or well region 118 under the gate structure 114 can be increased, thereby increasing the breakdown voltage at the source/drain of the HV semiconductor device 100 more significant.

In some embodiments, the first conductivity type and the second conductivity type are respectively p-type and n-type, and therefore the HV semiconductor device 100 is an n-type transistor, but not limited thereto. In some embodiments, the first conductivity type and the second conductivity type may also be n-type and p-type respectively, so the HV semiconductor device 100 is a p-type transistor.

As the HV semiconductor device 100 mentioned above, since the depth DP1 of the first isolation structure 106 is greater than the depth DP2 of the first drift region 108, and the width W1 of the first isolation structure 106 is greater than the width W3 of the first doped region 110, the breakdown voltage at drain/source can be significantly increased. Similarly, the disposition of the third isolation structure 136 can significantly increase the breakdown voltage at source/drain. The depth DP1 of the first isolation structure 106 and the depth of the third isolation structure 136 may be for example 300 nm respectively. It is noted that since the depth DP2 of the first drift region 108 is less than the depth DP1 of the first isolation structure 106, a channel length CL of the channel region 104 of the HV semiconductor device 100 may be controlled to be about 1 μm. If the depth of the first drift region is fabricated to be greater than the first isolation structure, such as greater than 300 nm, the channel length of the channel region needs to be enlarged to be greater than 2 μm, thereby limit the reduction of the size of the HV semiconductor device. However, in the HV semiconductor device 100 of this embodiment, by means of the depth DP1 of the first isolation structure 106 being greater than the depth DP2 of the first drift region 108, not only the breakdown voltage can be increased, but also the channel length CL of the channel region 104 can be maintained or reduced.

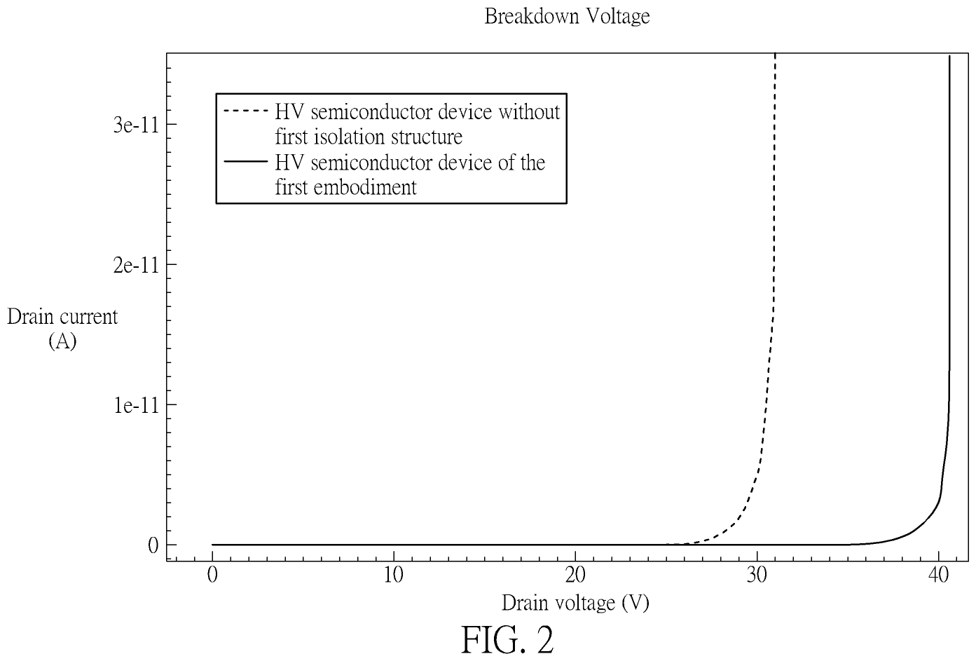

FIG. 2 schematically illustrates breakdown voltages of the HV semiconductor device according to the first embodiment and a HV semiconductor device without the first isolation structure. As shown in FIG. 2, the HV semiconductor device without the first isolation structure may have the breakdown voltage of about 30V at drain, but the HV semiconductor device 100 of the above embodiment may have the breakdown voltage of about 40V at drain. For this reason, the breakdown voltage of the HV semiconductor device 100 of the above embodiment is significant increased.

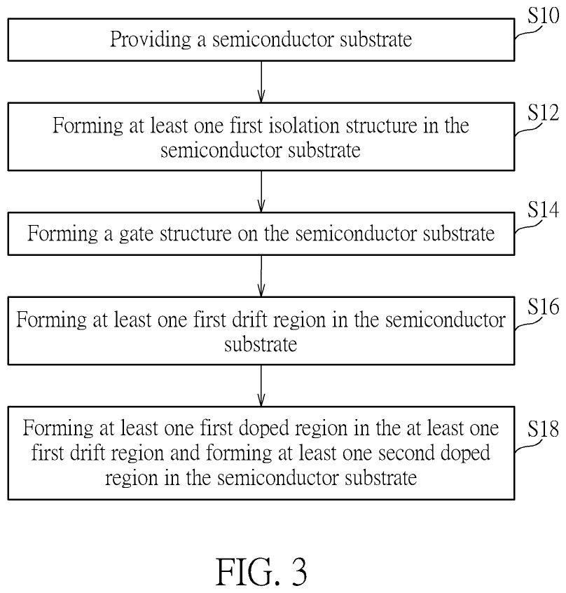

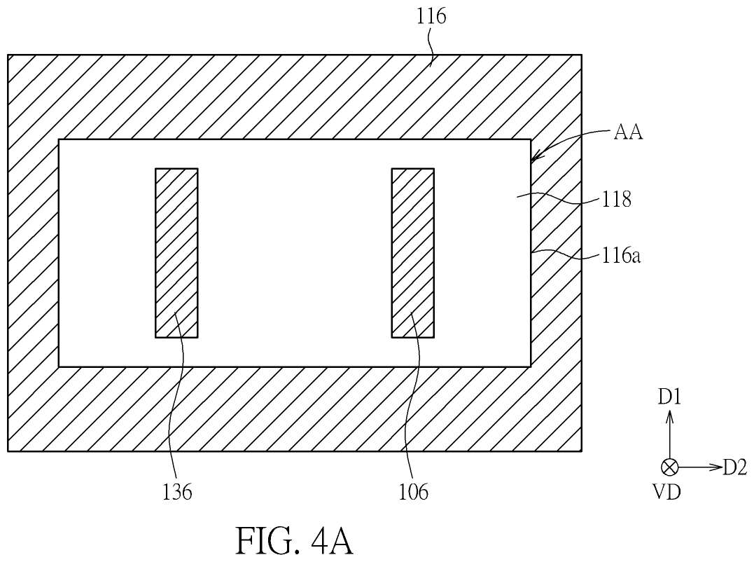

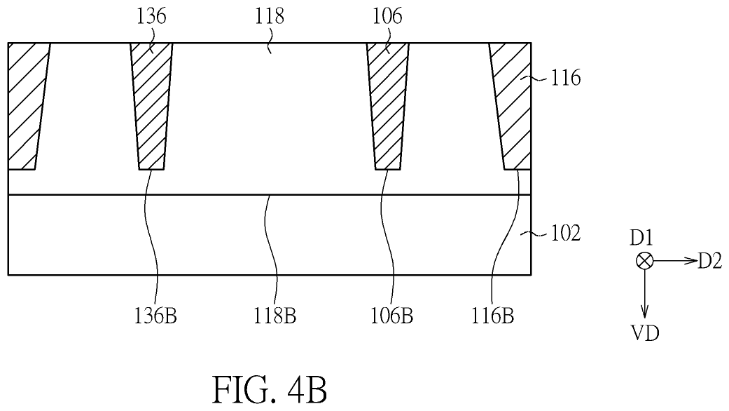

FIG. 3 schematically illustrates a flowchart of an exemplary method for manufacturing the HV semiconductor device according to the first embodiment. FIG. 4A-FIG. 5A and FIG. 1A schematically illustrate top views of exemplary structures at different steps of the exemplary method. FIG. 4B-FIG. 5B and FIG. 1B schematically illustrate sectional views of exemplary structures at different steps of the exemplary method. The method for manufacturing the HV semiconductor device of this embodiment includes but not limited to the following steps. First, as shown in FIG. 3, FIG. 4A and FIG. 4B, a step S10 is performed to provide the semiconductor substrate 102. In some embodiments, the step of providing the semiconductor substrate 102 may further include forming the well region 118 in the semiconductor substrate 102. After that, a step S12 is performed to format least one first isolation structure 106. In some embodiments, the step of forming the first isolation structure 106 may include forming the second isolation structure 116 in the semiconductor substrate 102 for defining the active area AA. In some embodiments, the step of forming the first isolation structure 106 may optionally further include forming the third isolation structure 136 in the semiconductor substrate 102, i.e. the first isolation structure 106, the second isolation structure 116 and the third isolation structure 136 may be formed at the same time. Thus, the bottom 106B of the first isolation structure 106, the bottom 116B of the second isolation structure 116 and the bottom 136B of the third isolation structure 136 are located at a same level. In some embodiments, the bottom 106B of the first isolation structure 106 may be shallower than the bottom 118B of the well region 118.

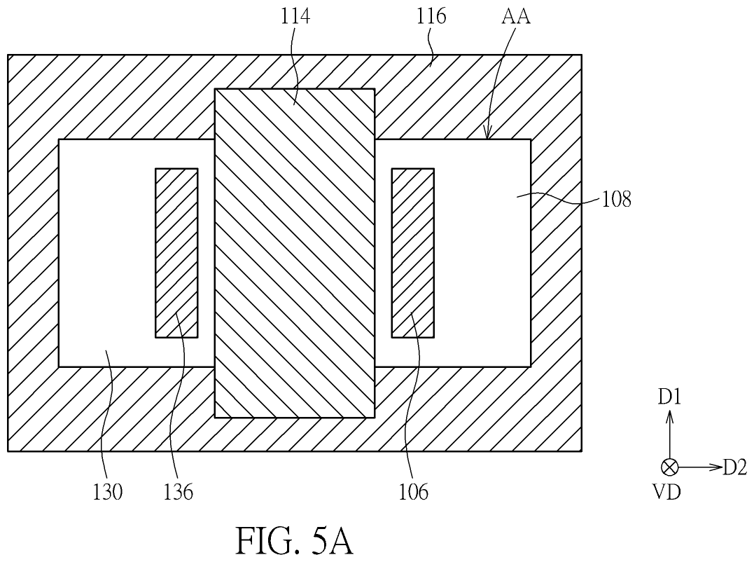

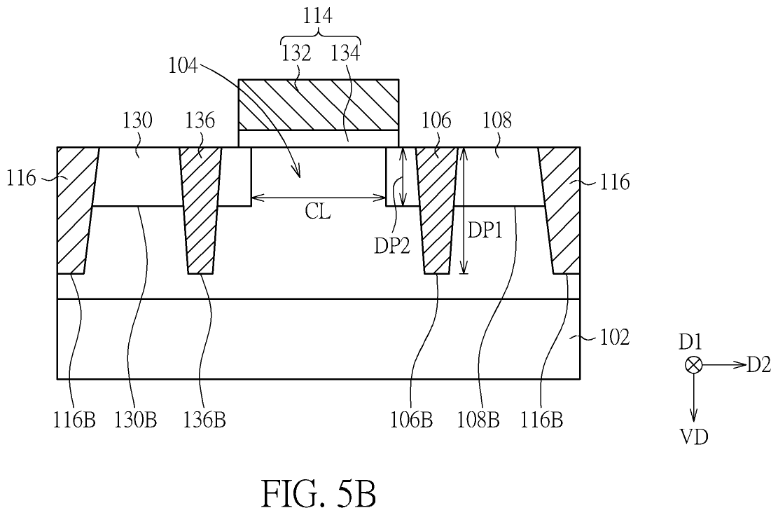

Subsequently, as shown in FIG. 3, FIG. 5A and FIG. 5B, a step S14 is performed to forming the gate structure 114 on the semiconductor substrate 102. Specifically, a dielectric layer and a conductive layer may be sequentially stacked on the semiconductor substrate 102, and then, the conductive layer and the dielectric layer are patterned in one step or different steps to form the gate electrode 132 and the gate dielectric layer 134. In some embodiments, the step of forming the gate structure 114 may further include forming spacer surrounding the gate electrode 132 and the gate dielectric layer 134. After the gate structure 114 is formed, a step S16 is performed to form the first drift region 108 in the active area of the semiconductor substrate 102 at a side of the gate structure 114. In some embodiments, the step of forming the first drift region 108 may further include forming the second drift region 130 in the active area of the semiconductor substrate 102 at another side of the gate structure 114 opposite to the first drift region 108. Accordingly, the channel region 104 can be formed between the first drift region 108 and the second drift region 130. For example, the first drift region 108 and the second drift region 130 may be formed by a self-aligning process utilizing the gate structure 114 and the above isolation structures as mask. In such situation, the channel length CL of the channel region 104 may be defined by the gate structure 114. In some embodiments, the step of forming the first drift region 108 and the second drift region 130 may be performed by utilizing an extra photomask, in such situation, the channel length CL of the channel region 104 is defined by the first drift region 108 and the second drift region 130. In some embodiments, the step of forming the first drift region 108 and the second drift region 130 may be performed before forming the first isolation structure 106, the second isolation structure 116 and the third isolation structure 136. In some embodiments, the step of forming the first drift region 108 and the second drift region 130 may be performed before forming the gate structure 114. Because the depth DP2 of the first drift region 108 is less than the depth DP1 of the first isolation structure 106, the annealing time for the first drift region 108 doesn't require too long. Accordingly, for the HV semiconductor device 100 with operating voltage of about 40V, the channel length CL can be easily controlled and reduced to be about 1 μm; for the HV semiconductor device 100 with operating voltage of about ten or more voltages, the channel length CL can be reduced to be less than 1 μm or less.

As shown in FIG. 3, FIG. 1A and FIG. 1B, a step S18 is performed to form the first doped region 110 in the first drift region 108 and the second doped region 112 in the second drift region 130 by utilizing another photomask. Accordingly, the HV semiconductor device 100 of this embodiment can be formed. Since the first doped region 110 and the second doped region 112 are not formed by means of utilizing the above isolation structures as mask, the formed first doped region 110 may be spaced apart from the first isolation structure 106, and the formed second doped region 112 may be spaced apart from the third isolation structure 136. In some embodiments, the gate structure 114 may be formed by a gate-last process, so the gate structure 114 may be formed after the formation of the first doped region 110 and the second doped region 112.

The HV semiconductor device and the manufacturing method thereof are not limited to the aforementioned embodiment and may have other different preferred embodiments. To simplify the description, the identical components in each of the following embodiments are marked with identical symbols. For making it easier to compare the differences between the embodiments, the following description will detail the dissimilarities among different embodiments and the identical features will not be redundantly described.

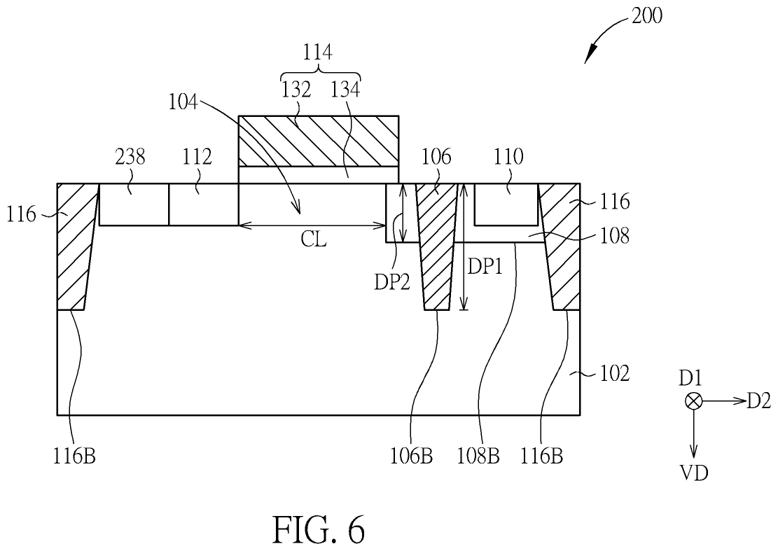

FIG. 6 is a schematic diagram illustrating a top view of an exemplary HV semiconductor device according to a second embodiment of the present invention. The HV semiconductor device 200 provided in this embodiment is different from the first embodiment in that the HV semiconductor device 200 may have high breakdown voltage at one terminal (drain or source). Specifically, the HV semiconductor device 200 doesn't include the second drift region and the third isolation structure in the first embodiment. In this embodiment, the HV semiconductor device 200 may further include a contact doped region 238 in the semiconductor substrate 102 and next to the second doped region 112. The contact doped region 238 may be formed after forming the second doped region 112 and has the second conductivity type. In some embodiments, the HV semiconductor device 200 may not include the well region.

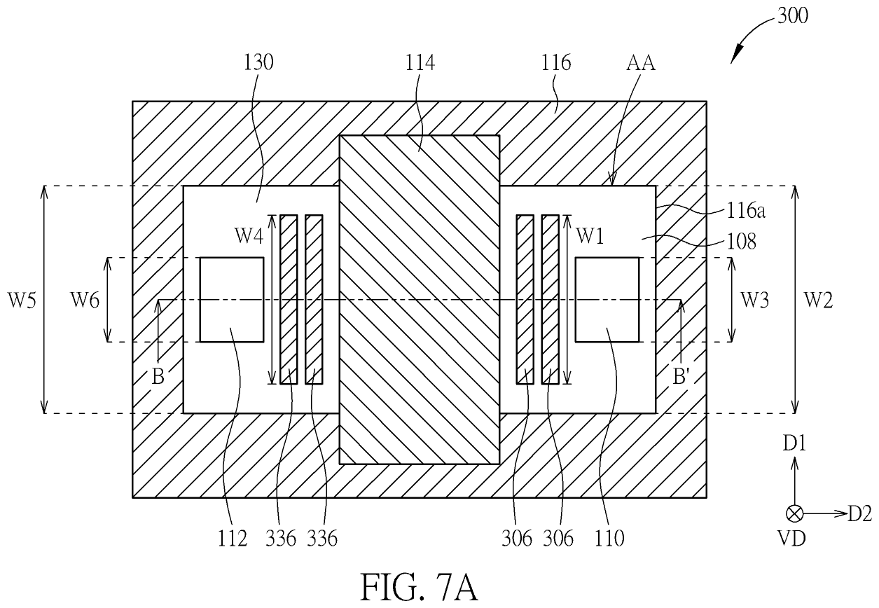

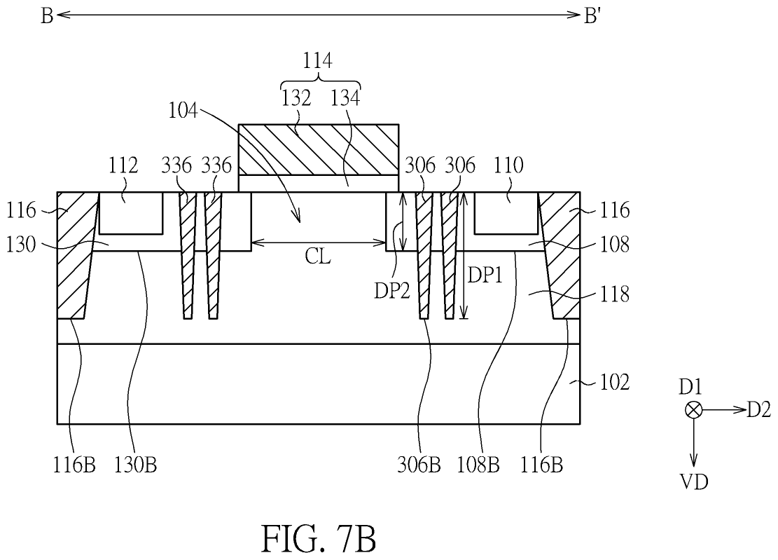

FIG. 7A is a schematic diagram illustrating a top view of an exemplary HV semiconductor device according to a third embodiment of the present invention, and FIG. 7B schematically illustrates a sectional view of the exemplary HV semiconductor device taken along a sectional line B-B′ of FIG. 7A. The HV semiconductor device 300 provided in this embodiment is different from the first embodiment in that the HV semiconductor device 300 includes a plurality of first isolation structures 306 arranged along the direction (e.g. the second direction D2) perpendicular to the extending direction of the gate structure 114. In this embodiment, each first isolation structure 306 may be similar to or the same as the first isolation structure of the first embodiment, and a width of each first isolation structure 306 in the second direction D2 may be adjusted according to the requirements of device characteristics. In some embodiments, the width W1 of at least one of the first isolation structures 306 may be between the width W3 of the first doped region 110 and the width W2 of the first drift region 108, and the width W1 of another one of the first isolation structures 306 may be less than the width W3 of the first doped region 110. In some embodiments, the bottom 306B of at least one of the first isolation structures 306 may be deeper than the bottom 108B of the first drift region 108, and the bottom 306B of another one of the first isolation structures 306 may be shallower than the bottom 108B of the first drift region 108. In some embodiments, the HV semiconductor device 300 may optionally include a plurality of third isolation structures 336 arranged along the second direction D2. The structure of the third isolation structures 336 may be similar to or the same as the first isolation structures 306 and will not be detailed.

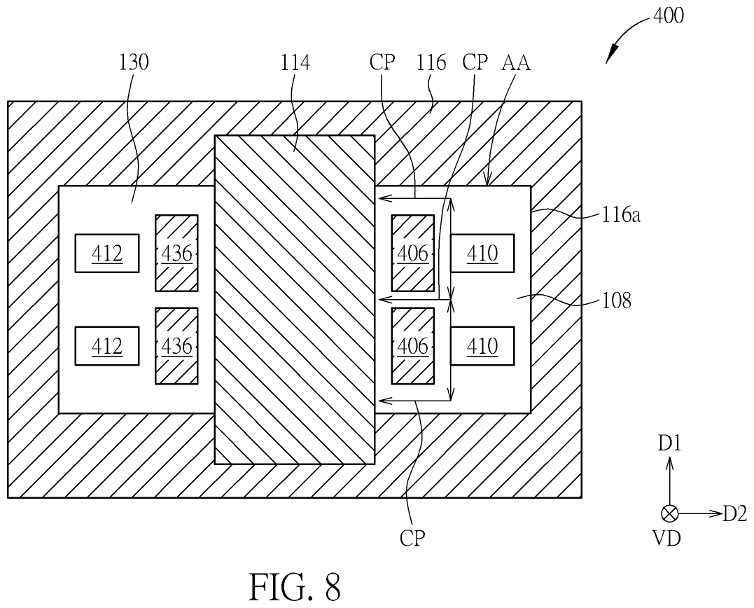

FIG. 8 is a schematic diagram illustrating a top view of an exemplary HV semiconductor device according to a fourth embodiment of the present invention. The HV semiconductor device 400 provided in this embodiment is different from the first embodiment in that the HV semiconductor device 400 includes a plurality of first isolation structures 406 arranged along the extending direction of the gate structure 114 (e.g. the first direction D1). In this embodiment, the first isolation structures 406 are spaced apart from each other, the HV semiconductor device 400 may also include a plurality of the first doped regions 410 disposed in the first drift region 108 and arranged along the first direction D1. Each first isolation structure 406 may be similar to or the same as the first isolation structure 106 of the first embodiment and vertically penetrates through the first drift region 108 and accordingly will not be detailed. Each first isolation structure 406 may be disposed between the corresponding first doped region 410 and the gate structure 114, so as to increase the current path CP from each first doped region 410 to the channel region. Specifically, the first doped regions 410 fully overlap the first isolation structures 406 in the direction (e.g. the second direction D2) perpendicular to the extending direction of the gate structure 114. That is, a width of each first isolation structure 406 in the first direction D1 is greater than a width of the corresponding first doped region 410 in the first direction D1. In some embodiments, the HV semiconductor device 400 may also include a plurality of first drift regions 108, and one of the first isolation structures 406 and one of the first doped regions 410 are disposed in each first drift region 108. In some embodiments, the HV semiconductor device 400 may optionally include a plurality of third isolation structures 436 arranged along the first direction D1 and a plurality of second doped regions 412 disposed in the second drift region 130 and arranged in the first direction D1. The structure of the third isolation structures 436 may be similar to or the same as the first isolation structures 406 and vertically penetrates through the second drift region 130 and will not be detailed. Each third isolation structure 436 may be disposed between the corresponding second doped region 412 and the gate structure 114, and a width of each third isolation structure 436 in the first direction D1 is greater than a width of the corresponding second doped region 412 in the first direction D1, so as to increase the current path from each second doped region 412 to the channel region. In some embodiments, the HV semiconductor device 400 may also include a plurality of second drift regions 130, and one of the second isolation structures 436 and one of the second doped regions 412 are disposed in each second drift region 130.

By using the disclosed HV semiconductor device and manufacturing method thereof, the depth of the isolation structure between the doped region and the gate structure can be greater than the depth of the drift region, and the width of the isolation structure in the first direction can be greater than the width of the doped region, so the breakdown voltage at drain/source can be significantly increased without increasing the channel length of the channel region or the channel length of the channel region can be reduced.

The foregoing description of the specific embodiments will so fully reveal the general nature of the present invention that others can, by applying knowledge within the skill of the art, readily modify and/or adapt, for various applications, such specific embodiments, without undue experimentation, and without departing from the general concept of the present invention. Therefore, such adaptations and modifications are intended to be within the meaning and range of equivalents of the disclosed embodiments, based on the invention and guidance presented herein. It is to be understood that the phraseology or terminology herein is for the purpose of description and not of limitation, such that the terminology or phraseology of the present specification is to be interpreted by the skilled artisan in light of the invention and guidance.

Embodiments of the present invention have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections can set forth one or more but not all exemplary embodiments of the present invention as contemplated by the inventor (s), and thus, are not intended to limit the present invention and the appended claims in any way.

Those skilled in the art will readily observe that numerous modifications and alterations of the device and method may be made while retaining the teachings of the invention. Accordingly, the above disclosure should be construed as limited only by the metes and bounds of the appended claims.

1-14. (canceled)

15. A method for manufacturing a high voltage semiconductor device, comprising:
providing a semiconductor substrate having a first conductivity type, wherein the semiconductor substrate has an active area;
forming at least one first isolation structure in the active area of the semiconductor substrate;
forming a gate structure on the active area of the semiconductor substrate at a side of the at least one first isolation structure; and
forming at least one first drift region in the active area of the semiconductor substrate at a side of the gate structure in a top view, and the at least one first drift region having a second conductivity type complementary to the first conductivity type, wherein a bottom of the at least one first isolation structure is deeper than a bottom of the at least one first drift region, and a part of the at least one first isolation structure under the at least one first drift region is in direct physical contact with the semiconductor substrate of the first conductive type.

16. The method for manufacturing the high voltage semiconductor device according to claim 15, further comprising forming at least one first doped region in the at least one first drift region, wherein the at least one first doped region has the second conductivity type, and the at least one first isolation structure is disposed between the gate structure and the at least one first doped region.

17. The method for manufacturing the high voltage semiconductor device according to claim 16, wherein a doping concentration of the at least one first drift region is less than a doping concentration of the at least one first doped region.

18. The method for manufacturing the high voltage semiconductor device according to claim 15, wherein forming the at least one first isolation structure comprises forming a second isolation structure in the semiconductor substrate, wherein the second isolation structure has an opening defining the active area.

19. The method for manufacturing the high voltage semiconductor device according to claim 18, wherein the at least one first isolation structure is spaced apart from the second isolation structure.

20. The method for manufacturing the high voltage semiconductor device according to claim 16, wherein forming the at least one first doped region comprises forming at least one second doped region in the active area of the semiconductor substrate at another side of the gate structure in the top view, and the at least one second doped region has the second conductivity type.

21. The method for manufacturing the high voltage semiconductor device according to claim 20, wherein forming the at least one first drift region comprises forming at least one second drift region in the semiconductor substrate, the at least one second drift region has the second conductivity type, the at least one second doped region is disposed in the at least one second drift region, and a doping concentration of the at least one second drift region is less than a doping concentration of the at least one second doped region.

22. The method for manufacturing the high voltage semiconductor device according to claim 21, wherein forming the at least one first isolation structure comprises forming a third isolation structure in the semiconductor substrate and between the at least one second doped region and the gate structure, and the third isolation structure vertically penetrating through the at least one second drift region.

23. The method for manufacturing the high voltage semiconductor device according to claim 15, wherein the gate structure is separated from the at least one first isolation structure in the top view.

24. The method for manufacturing the high voltage semiconductor device according to claim 15, wherein the at least one first drift region is formed after forming the gate structure.
